(19) United States
(12) Patent Application Publication
(10) Pub. No.: US 2024/0365687 A1
(43) Pub. Date: Oct. 31, 2024

(54) Enameled Superconductors

(71) Applicant: METOX TECHNOLOGIES, INC., Houston, TX (US)

(72) Inventors: Nagaraja SHASHIDHAR, Richmond, TX (US); Alex IGNATIEV, Houston, TX (US)

(73) Assignee: MetOx International, Inc., Houston, TX (US)

(21) Appl. No.: 18/683,960

(22) PCT Filed: Sep. 17, 2022
(86) PCT No.: PCT/US22/43908

§ 371 Date: Feb. 15, 2024

Related U.S. Application Data
(60) Provisional application No. 63/245,967, filed on Sep. 20, 2021.

(51) Int. Cl. H10N 60/20; H10N 60/01

(52) U.S. Cl. CPC H10N 60/20; H10N 60/0241

(57) ABSTRACT

Insulative superconductor coatings are provided which include amorphous ceramic thin films deposited at low temperature. The breakdown strength and thermal resistance performance of the insulative layer are advantageous even at very thin thicknesses and the mechanical strength characteristics are aided by compressive stress profiles resulting from the processes disclosed. The thin insulative layers thus enable unique superconductor architectures while maintaining high current density performance characteristics.

### CROSS REFERENCE TO RELATED APPLICATIONS

This application is a national stage application from PCT application PCT/US22/43908 filed Sep. 17, 2022, entitled “Enameled Superconductors” which claims priority and benefit from U.S. Provisional Patent Application No. 63/245,967 filed on Sep. 20, 2021, entitled “Enameled Superconductor” the content of which is incorporated in its entirety herein by reference.

### BACKGROUND OF THE INVENTION

### Technical Field

Embodiments of the subject matter disclosed herein generally relate to insulated superconductors and more particularly ceramic insulators, methods of applying ceramic insulators to high-temperature superconductors, and superconductor structures and architectures employing particular ceramic insulators.

### Discussion of the Background

Electrical insulation has an important role in the design and application of electro-magnetic systems utilizing coated conductors, particularly high-temperature superconductors. High temperature superconductors (HTS) provide the potential for development of superconducting components at higher operating temperatures compared to traditional superconductors that operate at liquid helium temperature (4.2K). Superconductors operating at the higher temperatures thus provide the ability to develop superconducting components and products that operate more economically. Thin film HTS material comprised of YBa₂Cu₃O₇₋ₓ (YBCO), is one of a group of oxide-based high temperature superconductors. After the initial discovery of YBCO superconductors, other superconductors were discovered having a similar chemical composition but with Y replaced by other rare earth elements. This family of superconductors is often denoted as REBCO where RE stands for Rare Earth and may include Y, La, Nd, Sm, Eu, Gd, Tb, Dy, Ho, Er, Tm, Yb or Lu. This material formed the basis for second generation or “2G” HTS wire technology which provides a more cost-effective material for manufacturing HTS tapes and wires.

Such HTS films are typically deposited as textured REBCO thin films which may include one or more buffer layers onto an atomically textured metal substrate. In the case of metal-organic chemical vapor deposition (MOCVD), an organic ligand may comprise a vapor phase precursor delivered to the substrate for a deposition reaction. In the manufacturing of High Temperature Superconductors (HTS) via chemical vapor deposition (CVD) or MOCVD processing is under vacuum conditions whereby a stainless steel or Hastelloy substrate tape is heated to high temperature, for example, 800° C. to 900° C. for the vapor phase precursor materials to deposit on the substrate tape and HTS film growth to occur. Following deposition of buffer and superconducting layers, one or more stabilizing and/or insulating layers may be applied.

Coated conductors of various types utilized in electro-magnetic systems have included several organic materials for insulation. In some superconductors, epoxies (with and without fiber glass reinforcements) are used to coat the conductors as well as pot coils in epoxy. For example, enameled superconductors used in magnets may be encapsulated or coated with organic polyimide or an epoxy resin comprised of polyepoxide or prepolymers and polymers which contain epoxide groups and applied by dip or spray coating. The lowest thickness reported for these enamels is approximately 4 microns (um). Thus, at a thermal conductivity of 0.8 W/m-k, a 4 um thick enamel would have a room temperature thermal resistance of 5×10⁻⁶ m²K/W.

In other cases, metals like brass tape may be laminated to the coated conductors. Even though brass is technically a conductor, it has a relatively high resistance compared to superconductors, and hence acts like an insulator. In some superconductor applications, in order to achieve high current densities, a coil may be wound without insulation. This approach results in coils with a time constant of non-insulated coils that is much higher than that of completely insulated coils due to the absence of insulation resistance, resulting in a very slow coil charge-discharge rate.

Complicating the design of insulated superconductor architecture, the application of insulation also decreases the engineering current density in systems, since it increases the volume occupied by the conductor-insulator system. For example, a typical coated conductor may be 100 um thick, but the insulation can easily add 50 um thus increasing the cross sectional area by 50% and thereby reducing the engineering current density.

In many applications, particularly HTS, an insulative layer is needed over the superconductor to prevent layer-to-layer transfer of current. For these reasons, new insulated superconductors, architectures, and system and material methodologies are needed. The insulative layer needs to be very thin (e.g., ˜2 um or less) while having sufficient mechanical properties to withstand Lorentz forces, high thermal conductivity to dissipate any heat generated, high dielectric breakdown strength to prevent conduction of current from layer to layer while maintaining low thermal resistance. Moreover, the insulative layer must be applied at a low temperature to avoid degradation of the superconducting characteristics of the wire.

### SUMMARY OF EXAMPLE EMBODIMENTS

According to an embodiment, there is a thin film composite superconducting article having a metallic substrate, a buffer layer, a superconducting layer, and a ceramic insulating layer with a thermal resistance less that 10−7 m2 K/W at 25 C and a breakdown voltage greater than 20V.

According to another embodiment, there is a thin film composite superconducting article having a metallic substrate, a buffer layer, a superconducting layer, and a ceramic insulating layer having a compressive mismatch relative to the superconducting layer when cooled to a temperature of s 77K or less. The mismatch is determined by the ratio of bulk coefficients of thermal expansion measured at room temperature of the ceramic insulating layer to that of the superconducting layer and is substantially 0.75 or less.

In a method embodiment, there is a method of forming a superconductor article that includes providing a metallic substrate, depositing a buffer layer upon the substrate, depositing a superconducting layer upon the buffer layer at a first temperature, depositing a ceramic insulating layer upon the superconducting layer at a second temperature and a compressive mismatch relative to the superconducting layer is established when cooled to a temperature of substantially 77K or less.

### BRIEF DESCRIPTION OF THE DRAWINGS

The accompanying drawings, which are incorporated in and constitute a part of the specification, illustrate one or more embodiments and, together with the description, explain these embodiments. Unless noted otherwise, elements in drawings are not to scale. In the drawings:

FIG. 1A shows an exemplary layered insulated superconductor.

FIG. 1B shows an exemplary encapsulated insulated superconductor.

FIG. 1C shows an exemplary multi-stack superconductor architecture as a pancake coil.

FIGS. 2A and 2B show exemplary filamented and bundled insulated superconductors

FIG. 3 shows an embodiment of a reinforced insulated superconductor.

FIGS. 4A-4C show exemplary methods of producing insulated Type I and II high temperature superconductors (HTS) and low temperature superconductors (LTS).

FIG. 5 shows an exemplary system for producing insulated superconductors.

### DETAILED DESCRIPTION OF EXAMPLES OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments may be discussed in particular regard to insulated high temperature superconductors (HTS) but the disclosed insulative systems and processes are applicable to other superconductors (e.g., low temperature superconductors (LTS)) and other solid or coated conductors as well. Additionally, certain embodiments employing amorphous boron nitride will be discussed as a preferred embodiment, but other inorganic ceramics may be applicable for insulated superconductors.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the described features, structures or characteristics may be combined in any suitable manner in one or more embodiments.

Embodiments disclosed herein include a superconductor with a thin coating of an inorganic insulator applied as a last step in the superconductor manufacturing process. In preferred embodiments, the insulator is a very thin coating (e.g., approximately 20 nm) of an amorphous ceramic such as boron nitride (BN). The coating is applied with a particular methodology such that a unique combination of conditions to be discussed below enable and increase its suitability to high temperature superconductors. The insulative amorphous boron nitride is deposited as a thin coating of approximately 20 nm while providing a dielectric breakdown voltage of approximately 20V or greater, a thermal resistance of approximately 5×10⁻⁹ m² K/W or less as measured at 25° C., while maintaining high mechanical properties, including high abrasion resistance. The process for application of the amorphous boron nitride may be deposition methods and conditions to be discussed below. The breakdown voltage at this thickness is ˜20 V. If the application requires a higher breakdown voltage a thicker coating, say 160 nm thick, will increase the breakdown voltage to 140V and increase thermal resistance of 5×10⁻⁸ m² K/W.

Superconductor tapes and wires may be coated accordingly and formed into product applications. For example, one or more superconducting wires or tapes may be wound into coils for making electromagnets and electromagnetic products, such as high strength magnets in magnetic resonance imaging (MRI) and nuclear magnetic resonance (NMR) devices and systems, or rotating machine applications such as motors and generators and a host of other applications. Additionally, multi-tape and multi-wire systems may also be similarly coated but with the insulative coating applied only to select portions or faces. For example, to be described in greater detail below, when multiple conductors are wound, the adjacent windings must be insulated against each other to ensure current travels in the designed pathways while leaving other sides not in contact with an adjacent winding uncoated to minimize overall conductor volume and cross-sectional area.

There are several characteristics required for an insulator to be suitable for superconductor applications. Firstly, high dielectric breakdown strength and high electrical resistance ensure that a higher voltage drop across the insulator is tolerated. This is a challenge given that the thickness of the insulator is preferably minimized to enhance other needs for superconductor applications such as high thermal conduction and lower overall conductor cross sectional area. A lower cross-sectional area allows for higher engineering current density which in turn permits higher magnetic field.

Very low thermal resistance of the insulator is also very important, particularly for superconductors given that any generated heat needs to be dissipated quickly to prevent quenching. Quenching is a phenomena whereby local heat buildup of a conductor increases local electrical resistance and in turn generates more heat in a cascading manner. Thus, the thermal resistance of the insulative material must be low making it capable of dissipating heat rapidly.

Mechanically, in addition to minimal insulator thickness, the uniformity of the thickness of the insulator as measured at each point around the conductor is important so that any local variations in dielectric breakdown strength are minimized in order to avoid the potential for shorting at positions where gaps or excessive thinness in the coating may be present. An advantage of thin layers is that layers essentially conform to the superconductor surface that allows the coil to have a large contact area between layers. This contact area allows the heat to be conducted away rapidly in the case of a quench.

Also, the insulative coating must be resistant to mechanical stress encountered during winding of the conductor which induces bending, stretching, and friction. This is a critical requirement since the total stresses experienced by the insulative coating is compounded by the internal stresses due to mismatches in the coefficients of thermal expansion (CTE) of the various layers within the architecture of the coated conductors. These forces are amplified when the wires are cooled to operational temperatures for superconductors below 77K. Upon energization, high Lorentz forces are further additive to the stress profile within a conductor, particularly a superconductor. Thus, insulators for such applications often need to be resistant to magnitudes of stress greater than that of typical copper windings. Additionally, the thermo-mechanical performance of the insulator at very low temperatures is very important such that the mechanical strength of the insulative coating is maintained at cryogenic temperatures (e.g., below 77K) as well as through multiple thermal cycles.

Superconductor operational conditions differ greatly from copper. While heat generated in copper coils due to ohmic heating may reach temperatures of 200 C or higher; superconductors operate at temperatures below −196 C and even below −268 C. Such thermal conditions have significant implications on the choice of materials. At low temperatures, most materials become brittle and break easily. Also, most polymer-based insulators, due to their high coefficient of thermal expansion, shrink significantly at temperatures below glass transition temperatures and do not deform to relieve shrinkage stresses. The glass transition temperature of a polymer is the temperature below which the polymers become glassy; that is rigid and non-plastic. Importantly, thermal conductivity is reduced as temperature declines, particularly for polymeric enamels which typically have lower initial (room temperature) thermal conductivity making them less suitable for superconductor applications. Inorganic ceramics are, on the other hand, generally good insulators having good electrical resistance and thermal properties, but producing them in a form that is suitable for very thin enamels for superconductors is a challenge.

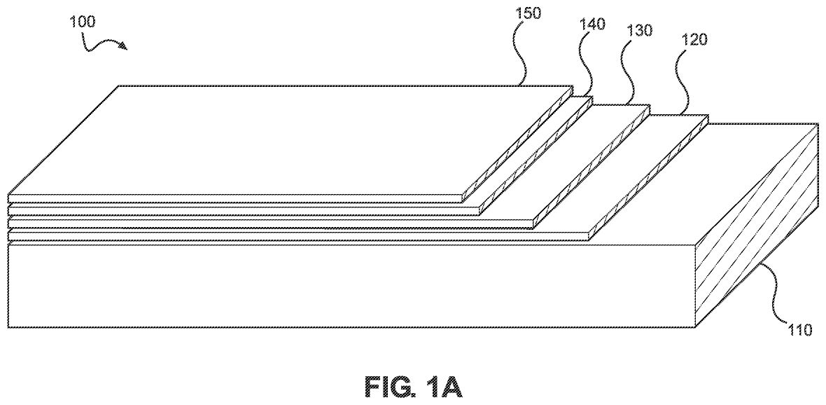

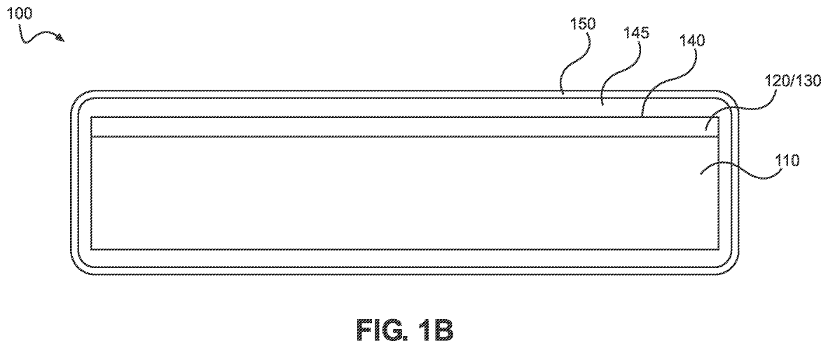

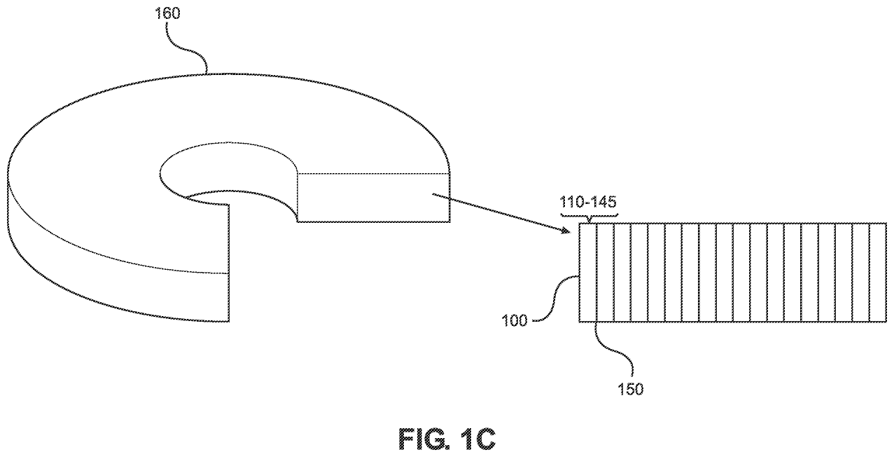

An example of an insulated coated superconductor tape 100 is shown in FIG. 1A. The superconductor may be a Type I or II High Temperature Superconductor (HTS) or a Low Temperature Superconductor (LTS) and be fabricated as single wires or tapes or cables comprised of multiple filaments or bundles of filaments, wires or tapes. The Type II superconductors are coated conductors typically several mm wide and less than one mm thick, giving the overall structure a rectangular cross section. In the Type II HTS example of FIG. 1A, the tape has a thin film composite structure with a basic architecture that includes a metallic substrate 110, a buffer layer 120, a superconducting layer 130, a capping or stabilizing layer 140 followed by an insulative coating 150. In this example, insulator 150 is shown for simplicity of illustration as only coating the uppermost surface but in preferred embodiments the insulator 150 may encapsulate the entire structure (110-150 in this example).

Multiple deposited layers of those shown in FIG. 1A or other layers may provide additional purpose to the basic architecture described herein. For example, FIG. 1B shows another Type II HTS where the superconductor layer 130 is deposited onto a metallic substrate tape 110. (The superconductor may be deposited on one or more buffer layers 130 first deposited on substrate 110.) The superconductor thin film may then be covered by a layer of metallic silver 140 which may then be encased in a copper layer 145. The insulating layer 150 is then deposited or applied such that the entirety of coated conductor architecture is enclosed in the insulative material.

In other examples, insulative layer 150 may be preferentially applied to certain sides or faces of a superconductor such as the pancake coil 160 illustrated in FIG. 1C which is comprised of a stack of multiple HTS tapes 100 sandwiched in close contact and wound into coils for magnet related applications. In this case, the tape 100 is wound around like a roll of tape where the side of one conductor 100 touches the other side of an adjacent conductor 100. Thin insulating layers 150 thus enable highly dense, compact superstructures and insulative coating 150 applied only to faces between adjacent conductors in this example further minimizes overall conductor volume.

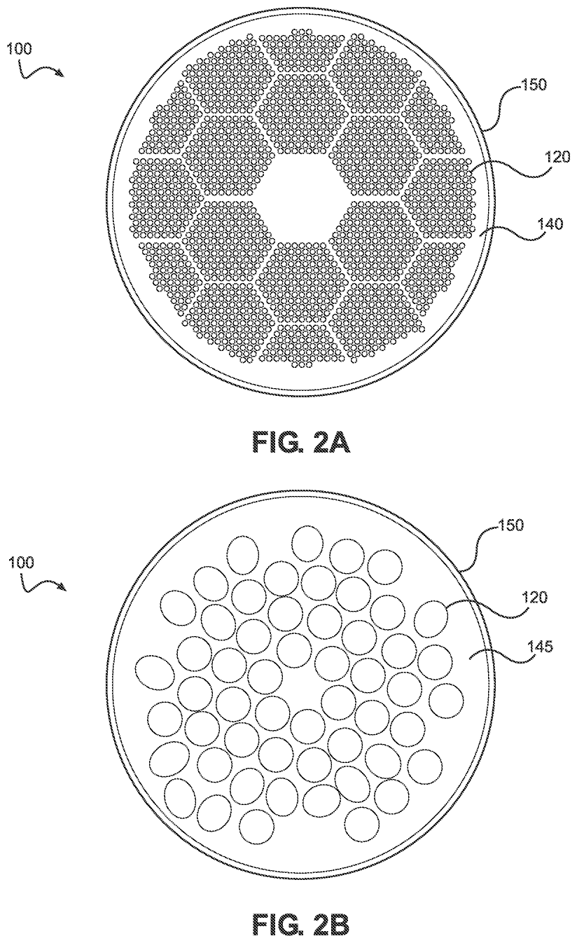

FIG. 2A shows a Type I superconductor where filaments of the superconductor 130 are arranged in bundles e.g., individual honeycomb units which are each embedded in a matrix of silver 140 and the insulating layer 150 is applied such that it encapsulates the entire architecture, which is shown as circular, but may also be comprised of rectilinear shaped elements within bundles of various shapes. FIG. 2B shows an exemplary low temperature superconductor (LTS) where superconductor 130 filaments are embedded in a matrix of copper 145 with the insulating layer 150 encapsulating the architecture. Filament bundles can also be fabricated with HTS wire through a variety of techniques with the filament strands then twisted to form HTS bundled wire.

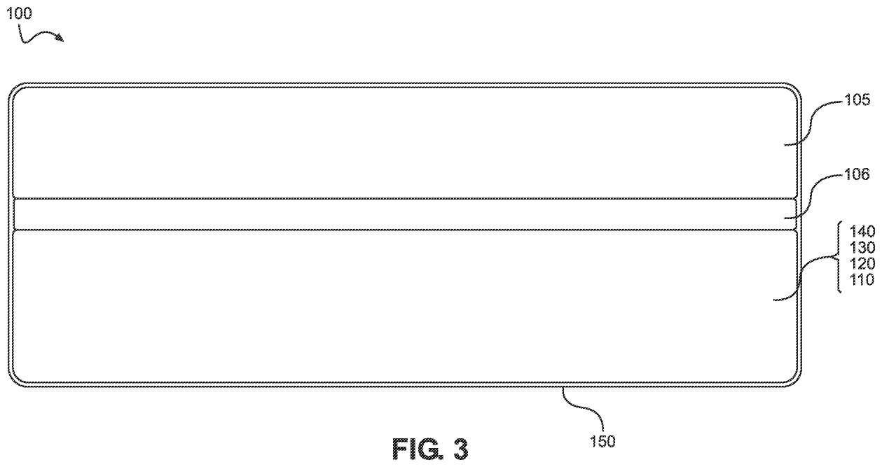

In certain applications the superconductor wire or tape 100 may be reinforced to limit the strain caused by Lorentz and other forces by laminating the basic architecture (e.g., 110-140) with a metal tape 105 such as steel or brass as shown in exemplary FIG. 3. In this example, the insulating layer 150 is applied over the entirety of the reinforced tape 100 after the reinforcing tape 105 is applied with a solder 106 (as an example) to the superconducting architecture 110-140. In other approaches, reinforcing tape 105 may be joined to the conductor via brazing or other type of metal-to-metal bonding method.

A number of insulative materials are used in their thin film form including HfO, MgO, SrTiO₃ and others including boron nitride (BN) which is widely used in its cubic (c-BN) and hexagonal (h-BN) phases due to its properties including high thermal conductivity, resistance to thermal shock and chemical inertness. The material in its cubic phase makes a durable hard coating and has improved chemical resistance at high temperatures. During the formation of c-BN, an intermediate material is formed, which is amorphous boron nitride (a-BN), which is transparent and insulative and thus useable as a dielectric in electronics.

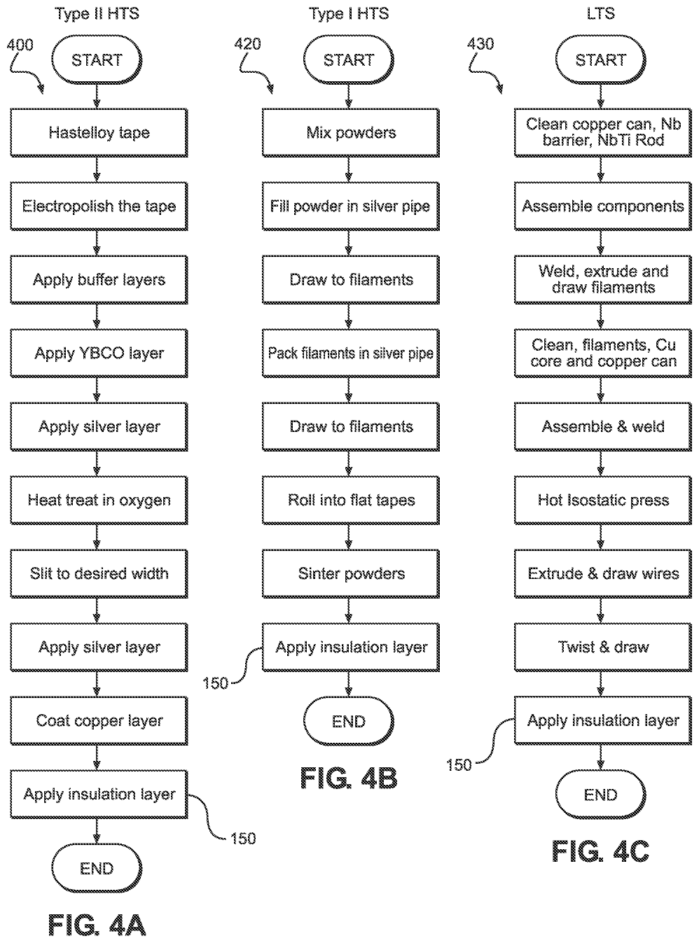

FIGS. 4A-C illustrate exemplary methods of producing insulated Type I HTS 400 and Type II HTS 420 and LTS 430 superconductors respectively. The typically final step common to the three types of superconductors entails depositing the insulative layer 150. The challenge is to deposit and grow a-BN at a lower temperature on a substrate such as a superconductor that is highly sensitive to heat. Traditionally, c-BN has been grown from borazine polymers at high temperatures using plasma assisted CVD at temperatures of approximately 900 C which would be unsuitable for superconductors due to the loss of lattice oxygen at high temperatures.

The superconductors 100 disclosed herein include insulative layers 150 of a-BN deposited or applied to the superconducting architectures at temperatures of approximately 200 C or less through utilization of less thermally intensive processing techniques including magnetron sputtering, RF sputtering, pulsed layer deposition (PLD), atomic layer deposition (ALD), plasma spray, binder spray, and e-beam evaporation.

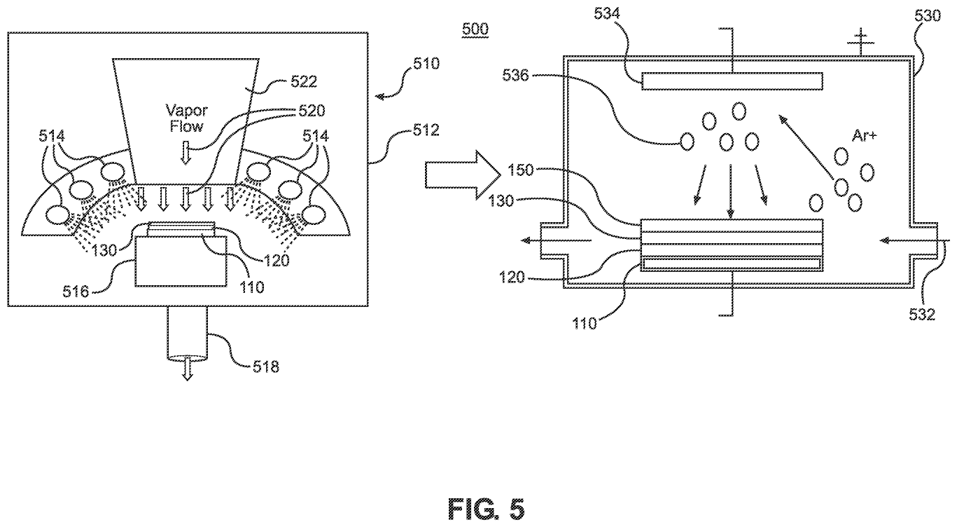

In one example, a-BN layers were deposited utilizing RF sputtering to a thickness of approximately 22 nm as illustrated in FIG. 5. The resultant insulative layer yielded the characteristics which include high electrical resistivity (ER) of ˜3×10¹² Ωcm with dielectric constants (DC) of y˜6.5 and a dielectric breakdown voltage (DBV) of ˜9.1 MV/cm. These parameters imply that with a thickness of ˜22 nm, the a-BN layer has a dielectric breakdown voltage of ˜20 V. It is difficult to measure or estimate the thermal conductivity (TC) of films with thinness measured in nanometers. However, h-BN has a thermal conductivity as high as 400 W/mK in c-axis at room temperature and ˜5 W/mK in a- and b-axis at room temperature. Cubic BN has a similar structure as diamond and has a thermal conductivity>700 W/mK. The amorphous boron nitride thus shows a thermal conductivity of approximately 3 W/mK.

The thermal resistance (TR) or the R-value is defined as the thickness divided by thermal conductivity (TC). For the 22 nm film dielectric breakdown strength (DBS) will be ˜20V and a thermal conductivity of 3 W/mK results in a thermal resistance of 5.3×10−9 m²K/W which indicates very little resistance (high thermal conductivity) for the flow of heat through the insulative layer. By comparison, for an insulation layer that is an order of magnitude thicker, or ˜160 nm, the dielectric breakdown voltage will increase to 140 V while the thermal resistance (TR) will be 5.3×10⁻⁸ m²K/W. Thus, depending on the break-down voltage required, the layer thickness can be tailored to obtain an effective heat transfer, while containing the voltage.

In another example, a 68 nm amorphous alumina layer is deposited over the superconductor. With a thermal conductivity of 1.73 W/m-K and a dielectric breakdown strength of 300 V/μm, this film would impart a dielectric breakdown voltage of 20 V and thermal resistance of 3.9×10⁻⁸ m²K/W at room temperature.

Operating temperatures for superconductors are typically below 77K for high temperature superconductors and 4.2K for low temperature superconductors. For the metallic components in an exemplary HTS superconductor 100, e.g., copper 140, silver 145 and Hastelloy C276 substrate 110, the (room temperature) coefficients of thermal expansion (CTE) are 16.7×10⁻⁶, 19×10⁻⁶, and 11.3×10⁻⁶/° C., respectively. As the temperature is decreased, the CTE also decreases. For example, the CTE of copper decreases from 16.7×10⁻⁶/° C. at room temperature to 10×10⁻⁶/° C. at 100K, to 2×10⁻⁶/° C. at 40K. Thus, since the volume fraction of metal substrate 110 is significantly greater than the superconductor thin film 130, the superconductor 130 as well as the insulative layer 150 are thus held in compression owing to the difference in relative expansion coefficients of the metallic components. This is of benefit since the compressive stress will first need to be overcome and then tensile stress applied for the insulative material to fail.

In a similar manner, the high expansion of the metals in the conductor will dictate the contraction of the superconductor insulator. When a-BN is applied (e.g., at 200 C) and subsequently cooled to operational temperature, the low CTE of this material of ˜3×10⁻⁶/° C. of will induce compressive stress to the film, since the higher thermal expansion components such as copper and Hastelloy shrinks more. This compressive stress helps particularly in maintaining the integrity of the layer as the super conducting tape is wound into coils.

For example, in the Type I superconductor illustrated in FIG. 2A, since the bulk superconductor 130 has a CTE of ˜14×10⁻⁶/° C. which is higher than a-BN (˜3×10⁻⁶/° C.), thus when cooled to an operating temperature of <77K the conductor would tend to contract more than the boron nitride, hence the insulator will be in compression, thereby protecting the outer coating from cracking. Similarly, the composite that is used in a structure such as that of FIG. 2B also has higher thermal expansion than boron nitride and hence will also cause the external surface to be in compression.

Recognizing that ceramic layers are much stronger when they are held in compression, particularly in the case of superconductor insulators, an a-BN film held in compression will ensure that these films perform well not just electrically and thermally, but also mechanically. Stress resistance to withstand the rigorous handling conditions of superconductors including windings and other processing stresses, is thus enabled by a-BN insulators even at minimal thickness.

As mentioned above, less thermally intensive processing techniques are required to successfully coat temperature sensitive superconductors. In a preferred embodiment, a Type II HTS tape 100 is fabricated using photo-assisted metal organic chemical vapor deposition (PAMOCVD) at an approximate temperature of 900 C followed by coating with an a-BN insulative layer deposited via RF sputtering at or near room temperature. FIG. 5 depicts an exemplary system 500 for producing an insulated superconductor via PAMOCVD combined with RF sputtering. In this example, simplified to show main components, an MOCVD reactor 510 is comprised of a vacuum housing 512 which encloses the deposition system components including radiation lamps 514 and hot block type susceptor 516 that supports and heats a typical stainless steel or Hastelloy translating substrate tape 110. Reactor 510 is maintained at vacuum via an outlet port 518 and precursor reactant(s) 520 are introduced via a showerhead 522. For MOCVD, precursor reactants 510 are preferably comprised of one or more organic ligands delivered as vapor phase components or in other embodiments may originate as solid phase components first vaporized prior to injection to showerhead 522. Substrate tape 110 is heated via susceptor 516 to approximately 800-900 C while radiation lamps 514 photo enhance thin film growth of one or more buffer 120 and superconductor layers 130 on substrate 110. As described above, one or more additional layers (not shown), e.g., a stabilizing coating 140 (not shown) may also be deposited after the superconductor thin film 130.

In a subsequent stage of system 500, a radio frequency sputtering (RFS) chamber 530 is provided to deposit the thin film insulative (e.g., a-BN) material 150. RF sputtering has many advantages such as simple, cost-effective equipment, high growth rate while maintaining high degrees of control of deposited thickness, good adhesion with high uniformity as well as good suitability for superconductors owing to low operating temperature.

RF sputtering operates at substantially room temperature and low pressure and relies on alternate current (AC) power instead of direct current (DC) power and alternates at a frequency in the RF range (5˜30 MHz). RF sputtering utilizes positive ions (e.g., Ar⁺) from sputtering gas 532 which are formed from a radio frequency discharge plasma to bombard the sputtering target 534 such that target atoms 536 are sputtered out and deposited on the surface of a grounded substrate. In preferred embodiments, in order to deposit the insulative layer 150 of a-BN, sputtering target 534 may be comprised of solid hexagonal boron nitride (h-BN). The grounded substrate in a HTS case is the product architecture provided from the PAMOCVD process 510 including metallic substrate 110, buffer 120 and superconducting thin film 130.

It should be noted that for purposes of clarity FIG. 5 depicts an example of these two coating related operations (PAMOCVD and RFS) though other production steps are necessary which are outlined in exemplary FIG. 4 and vary by type of superconductor. Also important, FIG. 5 shows distinct unit operations or batch mode production, but the entire system 500 may be operated in continuous or semi-continuous mode whereby initial substrate 110 is fed into the PAMOCVD chamber 510 via a reel-to-reel system which in turn may be transferred to separate reel-to-reel systems of subsequent stages (e.g., 540, 530). Alternatively, a single reel-to-reel system may feed all stages of system 500.

In a situation where an extremely thin film is applied on a relatively thick substrate (e.g., a 50 nm film on a 100 um thick superconducting tape, with a thickness ratio of 2000), the stresses in the film are given by

$$s = \frac{{E}_{f}}{( 1 - {v}_{f} )} ( {α}_{c} - {α}_{f} ) Δ T$$

Where E_{f} is the elastic modulus of the film (˜100 GPa), v_{f} is Poisson ratio (0.23), α is the thermal expansion coefficient (15×10⁻⁶ and 3×10⁻⁶ for conductor and coating, respectively) and ΔT is the temperature difference when the coating is applied and when it is used. The subscripts c and f denote the conductor and the film. In our example, when the coating is applied at 200 C and used at −196 C (77K) ΔT=396 C. These values indicate that the stress in the film is ˜620 MPa.

High stresses such as these typically result in the delamination of a coating, especially when the coated conductor is bent or formed into a coil. However, stresses are often lower than estimated because α_{c} and α_{f} decrease and become temperature independent as it is cooled to operational temperatures (−196 C and lower). Alternately, stresses can be induced in the film during the formation of the coating, which further reduces damage due to high stresses.

Unexpectedly, in a preferred embodiment utilizing a-BN, a very thin insulative coating to a HTS conductor provides advantageous performance characteristics including low thermal resistance given that the cryogenic thermal conductivity is an order of magnitude (or two, depending on the material) higher than at room temperature. This makes the thermal resistance one or two orders of magnitude lower than at room temperature.

With this system and process, a thin film composite superconducting article originating from a metallic substrate with a buffer layer and a superconducting layer deposited by MOCVD combined with the application by RFS at substantially room temperature (25 C) of a thin (e.g., 22 nm) inorganic ceramic insulating layer results in a robust superconductor architecture with an imparted compressive mismatch between the superconducting 130 and insulative 150 layers when cooled to a temperature of substantially 77K or less. The compressive mismatch is determined by the ratio of bulk coefficients of thermal expansion measured at room temperature of the ceramic insulating 150 layer and the superconducting 130 layer, which are in this example 3×10⁻⁶/° C. and 14×10⁻⁶/° C. respectively, which in turn results in ratio of bulk coefficients of thermal expansion (CTE) of approximately 0.21. The total stress in the coating is a sum of intrinsic stress (i.e., stress that is imparted during the coating process) and the thermal expansion stress. The intrinsic stress can be compressive or tensile depending on the coating conditions. For the total stresses in the coating to be negative, the CTE ratio of conductor to the coating are preferably less than approximately 0.75 to ensure the coating will be under compressive stress.

What is claimed is:

1. A thin film composite superconducting article comprising:
a metallic substrate;
a buffer layer;
a superconducting layer, and
a ceramic insulating layer comprising a thermal resistance less that 10⁻⁷ m² K/W at 25 C and a breakdown voltage greater than 20V.

2. The superconducting article of claim 1, wherein the ceramic insulating layer is comprised of an amorphous ceramic.

3. The superconducting article of claim 2, wherein the amorphous ceramic is boron nitride.

4. The superconducting article of claim 1, wherein the ceramic insulating layer is applied to the superconducting layer with a deposition temperature substantially equal to 200 C or less.

5. The superconducting article of claim 1, wherein the ceramic insulating layer is substantially 2 μm or less in thickness.

6. The superconducting article of claim 1, wherein the superconducting layer is a high temperature superconductor.

7. A thin film composite superconducting article comprising:
a metallic substrate;
a buffer layer;
a superconducting layer, and
a ceramic insulating layer having a compressive mismatch relative to the superconducting layer when cooled to a temperature of substantially 77K or less,
wherein said mismatch is determined by the ratio of bulk coefficients of thermal expansion measured at room temperature of the ceramic insulating layer to that of the superconducting layer,
wherein said ratio of bulk coefficients of thermal expansion is substantially 0.75 or less.

8. The superconducting article of claim 7, wherein the ceramic insulating layer is comprised of an amorphous ceramic.

9. The superconducting article of claim 8, wherein the amorphous ceramic is boron nitride.

10. The superconducting article of claim 7, wherein the ceramic insulating layer is applied to the superconducting layer with a deposition temperature substantially equal to 200 C or less.

11. The superconducting article of claim 7, wherein the ceramic insulating layer is substantially 2 μm or less in thickness.

12. The superconducting article of claim 7, wherein the superconducting layer is a high temperature superconductor.

13. A method of forming a superconductor article, the method comprising
providing a metallic substrate;
depositing a buffer layer upon the substrate;
depositing a superconducting layer upon the buffer layer at a first temperature; and
depositing a ceramic insulating layer upon the superconducting layer at a second temperature such that a compressive mismatch relative to the superconducting layer is established when cooled to a temperature of substantially 77K or less.

14. The method of claim 13, wherein the ceramic insulating layer is comprised of an amorphous ceramic.

15. The method of claim 14, wherein the amorphous ceramic is boron nitride.

16. The method of claim 13, wherein the ceramic insulating layer is deposited with a deposition temperature substantially equal to 200 C or less.

17. The method of claim 16, wherein the superconducting layer is deposited by MOCVD and the ceramic insulating layer is deposited by a different technique chosen from the group of RF sputtering, magnetron sputtering, pulsed laser deposition, atomic layer deposition or e-beam evaporation.

18. The method of claim 13, wherein the ceramic insulating layer is substantially 2 μm or less in thickness.

19. The method of claim 13, wherein the superconducting layer is a high temperature superconductor.

20. The method of claim 13, wherein the ceramic insulating layer comprises a thermal resistance less that 10⁻⁷ m² K/W at 25 C and a breakdown voltage greater than 20V.
